(19) United States
(12) Patent Application Publication
(10) Pub. No.: US 2025/0257448 A1
(43) Pub. Date: Aug. 14, 2025

(54) FILM FORMING METHOD AND FILM FORMING APPARATUS

(71) Applicant: Tokyo Electron Limited, Tokyo (JP)

(72) Inventors: Toru USUKI, Yamanashi (JP); Takashi FUSE, Yamanashi (JP); Shuji AZUMO, Yamanashi (JP); Yumiko KAWANO, Yamanashi (JP); Tomohiro NAKAGAWA, Yamanashi (JP)

(21) Appl. No.: 18/724,360

(22) PCT Filed: Dec. 21, 2022
(86) PCT No.: PCT/JP2022/047152

§ 371 Date: Jun. 26, 2024

(30) Foreign Application Priority Data
Jan. 6, 2022 (JP) 2022-001109

(51) Int. Cl. C23C 16/22; C23C 16/02; C23C 16/04; C23C 16/44; C23C 16/458; C23C 16/52

(52) U.S. Cl. CPC C23C 16/22; C23C 16/0245; C23C 16/042; C23C 16/4412; C23C 16/458; C23C 16/52

(57) ABSTRACT

A film forming method includes (A) providing a substrate including a first film and a second film in different regions of a surface of the substrate, the second film being formed of a material different from a material of the first film, (B) supplying modification gas formed into plasma to the surface of the substrate, thereby modifying the surface of the substrate, and (C) after (B), selectively forming a self-assembled monolayer on a surface of the second film rather than a surface of the first film. The modification gas used in (B) contains hydrogen and oxygen or contains hydrogen and nitrogen.

### TECHNICAL FIELD

The present disclosure relates to film forming methods and film forming apparatuses.

### BACKGROUND ART

Patent Literature 1 describes a film forming method that inhibits formation of the target film on a part of the substrate surface using a self-assembled monolayer (SAM) and forms the target film on another part of the substrate surface. The film forming method described in Patent Literature 1 performs alternating steps of exposing the substrate surface to a precursor of the SAM and exposing the substrate surface to a precursor of an OH group. The precursor of the SAM includes carboxylic acid. The precursor of the OH group includes water vapor.

### CITATION LIST

### Patent Literature

Patent Literature 1: PCT Japanese Translation Patent Publication No. 2019-512877

### SUMMARY OF THE INVENTION

### Problem to be Solved by the Invention

An aspect of the present disclosure provides a technique of increasing the density of a SAM.

### Means for Solving the Problem

A film forming method according to one aspect of the present disclosure includes (A) to (C) below. (A) Providing a substrate including a first film and a second film in different regions of a surface of the substrate, the second film being formed of a material different from a material of the first film. (B) Supplying modification gas formed into plasma to the surface of the substrate, thereby modifying the surface of the substrate. (C) After (B), selectively forming a self-assembled monolayer on a surface of the second film rather than a surface of the first film. The modification gas used in (B) contains hydrogen and oxygen or contains hydrogen and nitrogen. (C) includes: (Ca) supplying gas of carboxylic acid to a process chamber in a state in which the substrate is housed in the process chamber and an internal pressure of the process chamber is reduced, the gas of carboxylic acid being a precursor of the self-assembled monolayer; and (Cb) maintaining, for a set period of time, a state in which supply of the gas of the carboxylic acid to the process chamber is stopped or a state in which a flow rate of the gas of the carboxylic acid supplied is reduced compared to (Ca).

### Advantageous Effects of Invention

According to one aspect of the present disclosure, it is possible to increase the density of the SAM.

### BRIEF DESCRIPTION OF DRAWINGS

FIG. 1 is a flowchart illustrating a film forming method according to an embodiment.

FIG. 2A is a diagram illustrating an example of step S1.

FIG. 2B is a diagram illustrating an example of step S3.

FIG. 2C is a diagram illustrating an example of step S4.

FIG. 2D is a diagram illustrating an example of step S6.

FIG. 3 is a flowchart illustrating an example of a subroutine of step S4.

FIG. 4 is a flowchart illustrating an example of a subroutine of step S6.

FIG. 5A is a diagram illustrating a modified example of step S3.

FIG. 5B is a diagram illustrating a modified example of step S4.

FIG. 5C is a diagram illustrating a modified example of step S6.

FIG. 6 is a plan view illustrating a film forming apparatus according to an embodiment.

FIG. 7 is a cross-sectional view illustrating an example of a first processor of FIG. 6.

FIG. 8 is a graph illustrating a relationship between a water contact angle of a substrate surface obtained in Examples 1 to 3, and a supply stop time of PEBA gas.

FIG. 9 is a graph illustrating a relationship between a peak of F in an XPS spectrum of the substrate surface obtained in Example 1, and the supply stop time of the PFBA gas.

FIG. 10 is a graph illustrating a relationship between an atomic ratio of F to Ru determined from the XPS spectrum of the substrate surface obtained in Example 1, and the supply stop time of the PFBA gas.

FIG. 11 is a graph illustrating a relationship between a water contact angle of a substrate surface obtained in Examples 4 to 6, and the supply stop time of the PFBA gas.

FIG. 12 is a graph illustrating a water contact angle of a substrate surface obtained in Examples 7 to 13.

FIG. 13 is a graph illustrating a water contact angle of a substrate surface obtained in Examples 14 to 20.

### DETAILED DESCRIPTION OF THE INVENTION

Embodiments of the present disclosure will be described below with reference to the drawings. The same reference numerals are given to the same or corresponding components in the drawings, and description thereof may be omitted.

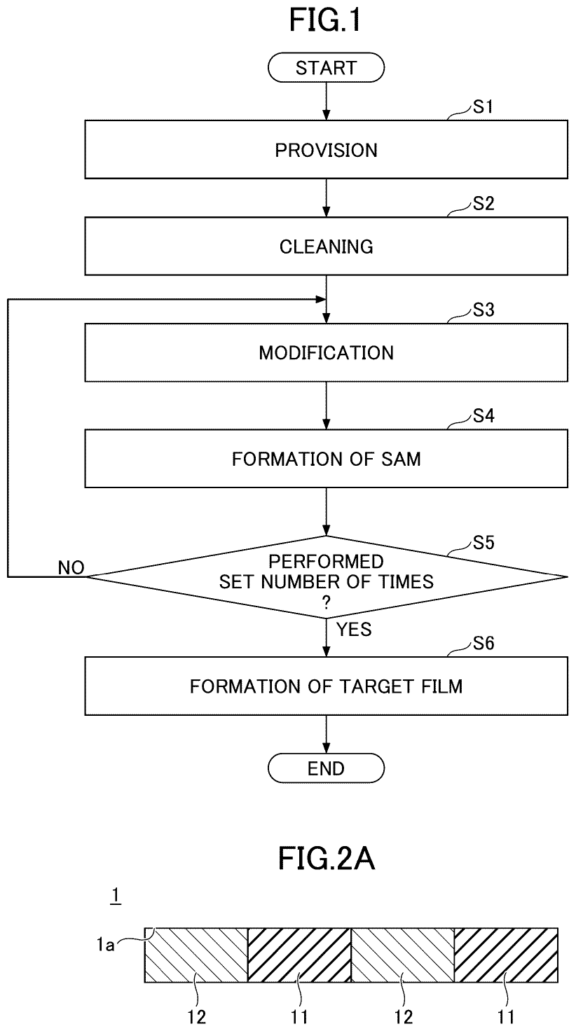

A film forming method according to an embodiment will be described with reference to FIGS. 1 to 4. The film forming method includes, for example, steps S1 to S6 as illustrated in FIG. 1. As long as the film forming method includes at least steps S1, S3, and S4, the film forming method need not include, for example, steps S2, S5, and S6. The film forming method may include a step or steps other than steps S1 to S6 illustrated in FIG. 1.

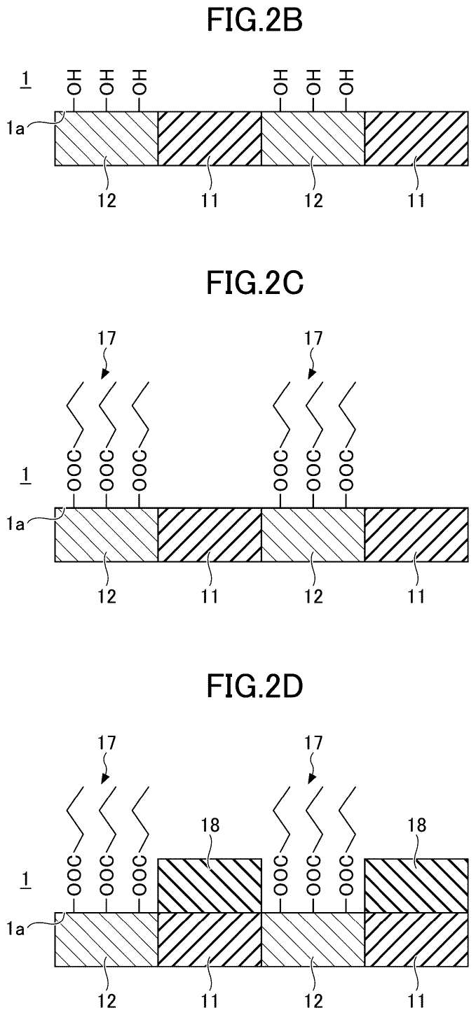

Step S1 of FIG. 1 includes providing a substrate 1 as illustrated in FIG. 2A. The substrate 1 includes an unillustrated underlying substrate. The underlying substrate is, for example, a silicon wafer, a compound semiconductor wafer, or a glass substrate.

The substrate 1 includes an insulating film 11 and a conductive film 12 in different regions of a substrate surface 1a. The substrate surface 1a is, for example, an upper surface of the substrate 1. The insulating film 11 and the conductive film 12 are formed on the underlying substrate. Another functional film may be formed between the underlying substrate and the insulating film 11 or between the underlying substrate and the conductive film 12. The insulating film 11 is an example of the first film, and the conductive film 12 is an example of the second film. No particular limitation is imposed on a material of the first film and a material of the second film.

The insulating film 11 is, for example, an interlayer insulating film. The interlayer insulating film is preferably a low-dielectric-constant (low-k) film. No particular limitation is imposed on the insulating film 11. The insulating film 11 is, for example, a SiO film, a SiN film, a SiOC film, a SiON film, or a SiOCN film. Here, the SiO film means a film containing silicon (Si) and oxygen (O). An atomic ratio of Si and O in the SiO film is typically 1:2. However, the atomic ratio thereof is not limited to 1:2. Similarly, the SiN film, the SiOC film, the SiON film, and the SiOCN film mean that they contain recited elements, and atomic ratios thereof are not limited to stoichiometric ratios. The insulating film 11 has a recess at the substrate surface 1a. The recess is a trench, a contact hole, or a via hole.

The conductive film 12 is, for example, filled in the recess of the insulating film 11. The conductive film 12 is, for example, a metal film. The metal film is, for example, a Cu film, a Co film, a Ru film, or a W film. The conductive film 12 may be a cap film. That is, an unillustrated second conductive film may be embedded in the recess of the insulating film 11, and the second conductive film may be covered by the conductive film 12. The second conductive film is formed of a metal different from that of the conductive film 12.

Although not illustrated, the substrate 1 may further include a third film on the substrate surface 1a. The third film is, for example, a barrier film. The barrier film is formed between the insulating film 11 and the conductive film 12, and suppresses diffusion of metal from the conductive film 12 to the insulating film 11. No particular limitation is imposed on the barrier film, which is, for example, a TaN film or a TiN film. Here, the TaN film means a film containing tantalum (Ta) and nitrogen (N). An atomic ratio of Ta and N in the TaN film is typically 1:1. However, the atomic ratio thereof is not limited to 1:1. Similarly, the TiN film means that it contains recited elements, and is not limited to the stoichiometric ratio.

Although not illustrated, the substrate 1 may further include a fourth film on the substrate surface 1a. The fourth film is, for example, a liner film. The liner film is formed between the conductive film 12 and the barrier film. The liner film is formed on the barrier film and assists the formation of the conductive film 12. The conductive film 12 is formed on the liner film. No particular limitation is imposed on the liner film, which is, for example, a Co film or a Ru film.

Step S2 of FIG. 1 includes cleaning the substrate surface 1a. Unillustrated contaminants present on the substrate surface 1a can be removed. The contaminants include, for example, a metal oxide, an organic substance, or both. The metal oxide is an oxide formed, for example, by reaction of the conductive film 12 with the atmosphere, and is what is called a native oxide film. The organic substance is, for example, a deposit containing carbon, and adheres during processing of the substrate 1. The cleaning of the substrate surface 1a may be a dry treatment or a wet treatment.

For example, step S2 includes supplying cleaning gas to the substrate surface 1a. The cleaning gas may be formed into plasma in order to increase removal efficiency of the contaminants. The cleaning gas includes reductive gas, such as H₂ gas and the like. The reductive gas can remove both of the metal oxide and the organic substance.

An example of the process condition in step S2 is described below.
Flow rate of H₂ gas: from 200 sccm through 10,000 sccm
Flow rate of Ar gas: from 20 sccm through 2,000 sccm
Power frequency for plasma generation: from 400 kHz through 40 MHz
Power for plasma generation: from 50 W through 1,000 W
Process time: from 10 seconds through 10 minutes
Process temperature (substrate temperature): from 100° C. through 250° C.
Process pressure: from 100 Pa through 2,000 Pa

Step S3 of FIG. 1 modifies the substrate surface 1a as illustrated in FIG. 2B. For example, step S3 supplies modification gas formed into plasma to the substrate surface 1a, thereby modifying the substrate surface 1a. When the modification gas contains hydrogen and oxygen, the modification gas can add OH groups to the surface of the conductive film 12, and can cause dehydration condensation reaction with carboxy groups (COOH groups) in step S4 as described below. The modification gas is, for example, H₂O gas, a gas mixture of H₂ and O₂, or a gas mixture of H₂ and O₃.

An example of the process condition in step S3 is described below.
Flow rate of H₂O gas: from 20 sccm through 1,000 sccm
Flow rate of Ar gas: from 0 sccm through 2,000 sccm
Power frequency for plasma generation: from 400 kHz through 40 MHz
Power for plasma generation: from 50 W through 1,000 W
Process time: from 10 seconds through 10 minutes
Process temperature (substrate temperature): from 100° C. through 250° C.
Process pressure: from 100 Pa through 2,000 Pa

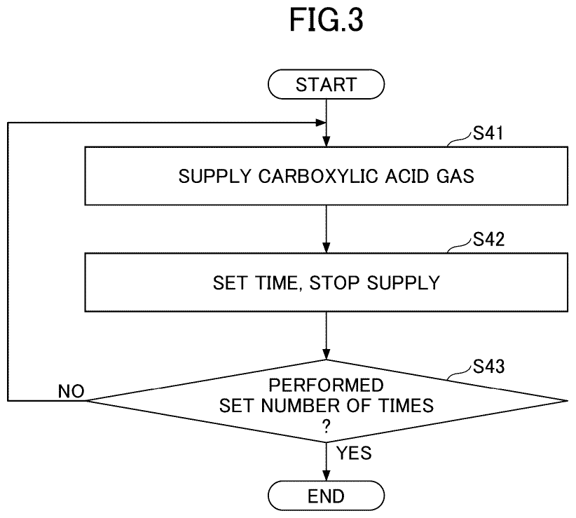

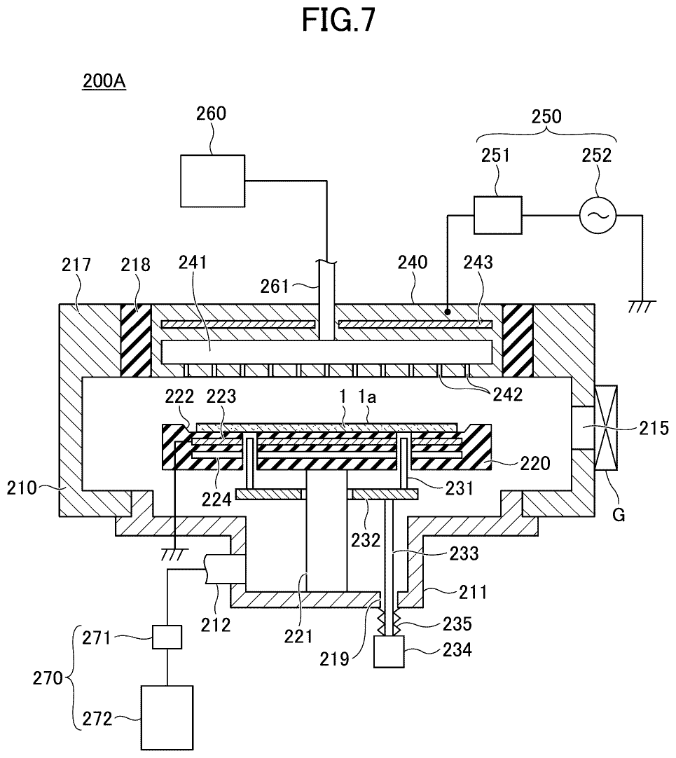

Step S4 of FIG. 1 includes selectively forming a SAM 17 on the surface of the conductive film 12 rather than the surface of the insulating film 11 as illustrated in FIG. 2C. Step S4 includes steps S41 and S42 as illustrated in FIG. 3. Steps S41 and S42 are performed in a state in which the substrate 1 is housed in the process chamber (e.g., a process chamber 210 as illustrated in FIG. 7) and the internal pressure of the process chamber is reduced. The order of steps S41 and S42 may be in reverse.

Step S41 includes supplying gas of carboxylic acid, a precursor of the SAM 17, into the process chamber. The carboxylic acid contains a carboxy group (COOH group) and is represented by general formula “R—COOH”. For example, R is a hydrocarbon group or is a group obtained by substituting at least one hydrogen of a hydrocarbon group with fluorine.

The carboxylic acid includes, for example, at least one selected from the group consisting of CF₃(CF₂)₂COOH, CF₃COOH, C₆H₅COOH, and CH₃(CH₂)ₙCOOH (n is an integer of from 2 through 10). In the following, CF₃(CF₂)₂COOH is also described as PFBA (Perfluorobutyric acid).

Carboxylic acid is more likely to chemically adsorb on the surface of the conductive film 12 than on the surface of the insulating film 11. According to the present embodiment, the OH group is added to the surface of the conductive film 12 in step S3, and thus dehydration condensation reaction between the OH group and the COOH group occurs, and the SAM 17 is selectively formed on the surface of the conductive film 12.

Carboxylic acid is more likely to chemically adsorb on the surface of a Ru film than is a thiol-based compound. Therefore, when the conductive film 12 is a Ru film, the density of the SAM 17 can be increased. Also, carboxylic acid can form the SAM 17 that is excellent in high-temperature resistance, compared to the thiol-based compound. Therefore, the process temperature in step S6 (formation of the target film), which will be described below, can be set to be high.

Step S42 includes maintaining, for a set period of time, a state in which supply of the gas of the carboxylic acid to the process chamber is stopped. The carboxylic acid remaining in the process chamber is chemically adsorbed on the surface of the conductive film 12. Therefore, the density of the SAM 17 can be increased. Further, efficiency of carboxylic acid in use can be increased. The set period of time is, for example, from 5 minutes through 1 hour and preferably from 30 minutes through 60 minutes.

Instead of maintaining, for the set period of time, the state in which the supply of the gas of the carboxylic acid to the process chamber is stopped, step S42 may include maintaining, for a set period of time, a state in which a flow rate of the gas of the carboxylic acid supplied is reduced compared to step S41. In this case, the density of the SAM 17 can be increased. Also, efficiency of carboxylic acid in use can be increased.

Step S42 preferably includes maintaining, for a set period of time, a state in which supply of all of gases to the process chamber is stopped. This can prevent dilution of the carboxylic acid, remaining in the process chamber, with the other gases. Thereby, the dehydration condensation reaction between the COOH group and the OH group can be promoted, and the density of the SAM 17 can be increased.

The internal pressure of the process chamber in step S42 may be lower than the internal pressure of the process chamber in step S41. By maintaining the internal pressure at a low level, it is possible to prevent H₂O, produced in the dehydration condensation reaction, from re-attaching to the SAM 17, i.e., reverse reaction. In step S42, an opening degree of a pressure adjusting valve of a pressure regulator (e.g., a pressure regulator 271 in FIG. 7), configured to regulate the internal pressure of the process chamber, is maintained to be constant.

Step S43 includes checking whether or not steps S41 and S42 have been performed a set number of times. If the set number of times has not been reached (step S43, NO), steps S41 and S42 are performed again because the density of the SAM 17 is insufficient. Meanwhile, when the set number of times has been reached (step S43, YES), the current process is ended because the density of the SAM 17 is sufficient.

The set number of times in step S43 may be one, but is preferably two or more. By repeatedly performing the supply of carboxylic acid and the stop of the supply thereof, the supply of the carboxylic acid can be performed in a divided manner, and efficiency of carboxylic acid in use can be further increased. The set number of times in step S43 is, for example, from 2 through 15.

An example of the process condition in step S4 is described below.
Step S41
Flow rate of PFBA gas: from 10 sccm through 100 sccm
Process time: from 30 seconds through 10 minutes
Process pressure: from 100 Pa through 300 Pa
Step S42
Process time: from 5 minutes through 1 hour
Process pressure: from 10 Pa through 100 Pa
Common process condition in steps S41 and S42
Process temperature: from 100° C. through 250° C.

Step S5 of FIG. 1 includes checking whether or not steps S3 and S4 have been performed a set number of times. If the set number of times has not been reached (step S5, NO), the density of the SAM 17 is insufficient, and thus steps S3 and S4 are performed again. Meanwhile, when the set number of times has been reached (step S5, YES), the density of the SAM 17 is sufficient, and thus the current process is ended.

The set number of times in step S5 may be one, but preferably two or more. By repeatedly performing steps S3 and S4, the surface of the conductive film 12 can be supplemented with the OH group in the middle of the supply of carboxylic acid, and the dehydration condensation reaction between the COOH group of the carboxylic acid and the OH group can be promoted. The set number of times in step S5 is, for example, from 2 through 15.

Step S6 in FIG. 1 includes forming a target film 18 on the surface of the insulating film 11 while inhibiting the formation of the target film 18 on the surface of the conductive film 12 using the SAM 17, as illustrated in FIG. 2D. The target film 18 is, for example, an insulating film and is formed on the insulating film 11. According to the present embodiment, the density of the SAM 17 is high, and thus blocking performance of the SAM 17 is high.

No particular limitation is imposed on the target film 18, which is, for example, an AlO film, a SiO film, a SiN film, a Zro film, an HfO film, or the like. Here, the AlO film means a film containing aluminum (Al) and oxygen (O). An atomic ratio of Al and O in the AlO film is typically 2:3. However, the atomic ratio thereof is not limited to 2:3. Similarly, the SiO film, the SiN film, the Zro film, and the HfO film mean that they contain recited elements, and atomic ratios thereof are not limited to stoichiometric ratios. The target film 18 is formed through CVD (Chemical Vapor Deposition) or ALD (Atomic Layer Deposition).

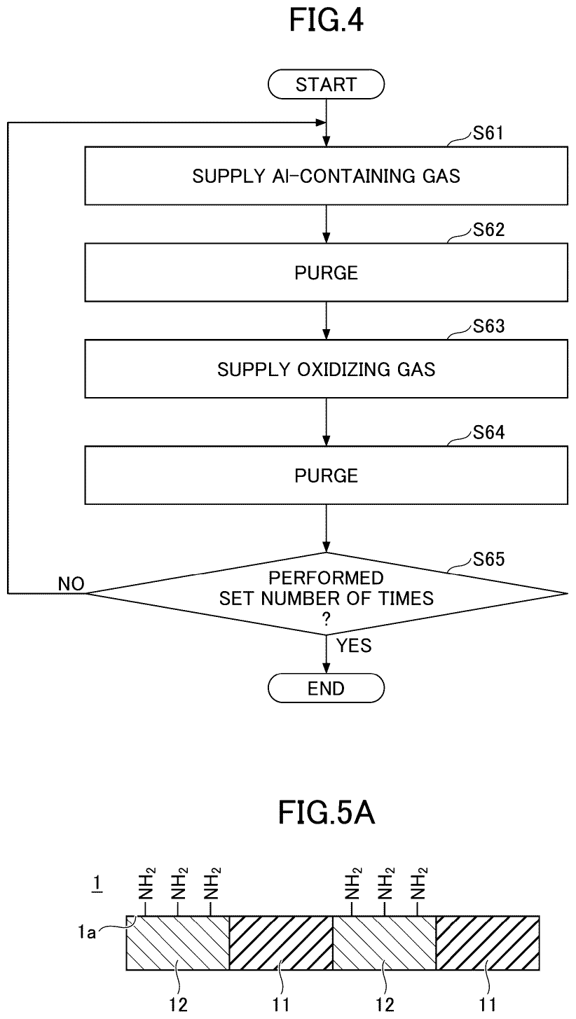

When the AlO film is formed through ALD, an Al-containing gas, such as TMA (trimethylaluminum) gas or the like, and an oxidizing gas, such as water vapor (H₂O gas) or the like, are alternately supplied to the substrate surface 1a. A method of forming the AlO film includes, for example, steps S61 to S65 as illustrated in FIG. 4.

Step S61 includes supplying an Al-containing gas to the substrate surface 1a. Step S62 includes supplying an inert gas, such as Ar gas or the like, to the substrate surface 1a and purging the excess Al-containing gas not adsorbed to the substrate surface 1a. Step S63 includes supplying an oxidizing gas to the substrate surface 1a. Step S64 includes supplying an inert gas, such as Ar gas or the like, to the substrate surface 1a and purging the excess oxidizing gas not adsorbed to the substrate surface 1a. The order of steps S61 and S63 may be in reverse.

Step S65 includes checking whether or not steps S61 to S64 have been performed a set number of times. If the set number of times has not been reached (step S65, NO), steps S61 to S64 are performed again. Meanwhile, when the set number of times has been reached (step S65, YES), the current process is ended because the thickness of the AlO film has reached the target film thickness. The set number of times in step S65 is set in accordance with the target film thickness of the AlO film, but is, for example, from 20 times through 80 times.

An example of the process condition in step S6 is described below.
Step S61
Flow rate of TMA gas: 50 sccm
Process time: from 0.1 seconds through 2 seconds
Step S62
Flow rate of Ar gas: from 1,000 sccm through 8,000 sccm
Process time: from 0.5 seconds through 2 seconds
Step S63
Flow rate of H₂O gas: from 50 sccm through 200 sccm
Process time: from 0.5 seconds through 2 seconds
Step S64
Flow rate of Ar gas: from 1,000 sccm through 8,000 sccm
Process time: from 0.5 seconds through 5 seconds
Common process condition in steps S61 to S64
Process temperature: from 100° C. through 250° C.
Process pressure: from 133 Pa through 1,200 Pa

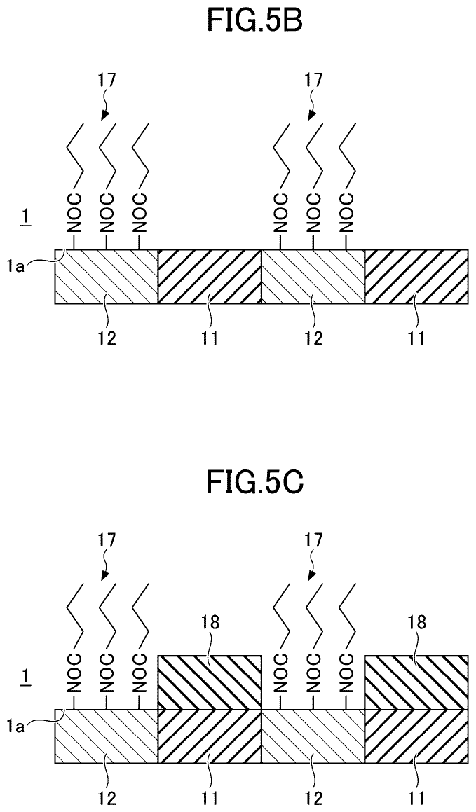

Next, a film forming method according to a modified example will be described with reference to FIG. 5. Steps S1 and S2 of the present modified example are the same as steps S1 and S2 of the above embodiment, and thus description thereof will be omitted. Step S3 of the present modified example modifies the substrate surface 1a as illustrated in FIG. 5A. When the modification gas contains hydrogen and nitrogen, the modification gas can add NH groups to the surface of the conductive film 12, and can cause dehydration condensation reaction with carboxy groups (COOH groups) in step S4 as described below. The modification gas is, for example, a gas mixture of H₂ and N₂, or NH₃ gas.

An example of the process condition in step S3 is described below.
Flow rate of H₂ gas: from 100 sccm through 2,000 sccm
Flow rate of N₂ gas: from 100 sccm through 2,000 sccm
Power frequency for plasma generation: 40 MHz
Power for plasma generation: 200 W
Process time: from 10 seconds through 60 seconds
Process temperature (substrate temperature): from 100° C. through 250° C.
Process pressure: from 200 Pa through 2,000 Pa

As illustrated in FIG. 5B, step S4 of the present modified example includes selectively forming the SAM 17 on the surface of the conductive film 12 rather than the surface of the insulating film 11. Step S4 of the present modified example is the same as step S4 of the above embodiment except that the SAM 17 is formed by utilizing dehydration condensation reaction between the NH group and the COOH group, and thus description thereof will be omitted.

Then, steps S5 and S6 are performed. Step S5 is the same as step S5 of the above embodiment, and thus description thereof will be omitted. As illustrated in FIG. 5C, step S6 includes forming the target film 18 on the surface of the insulating film 11 while inhibiting the formation of the target film 18 on the surface of the conductive film 12 using the SAM 17.

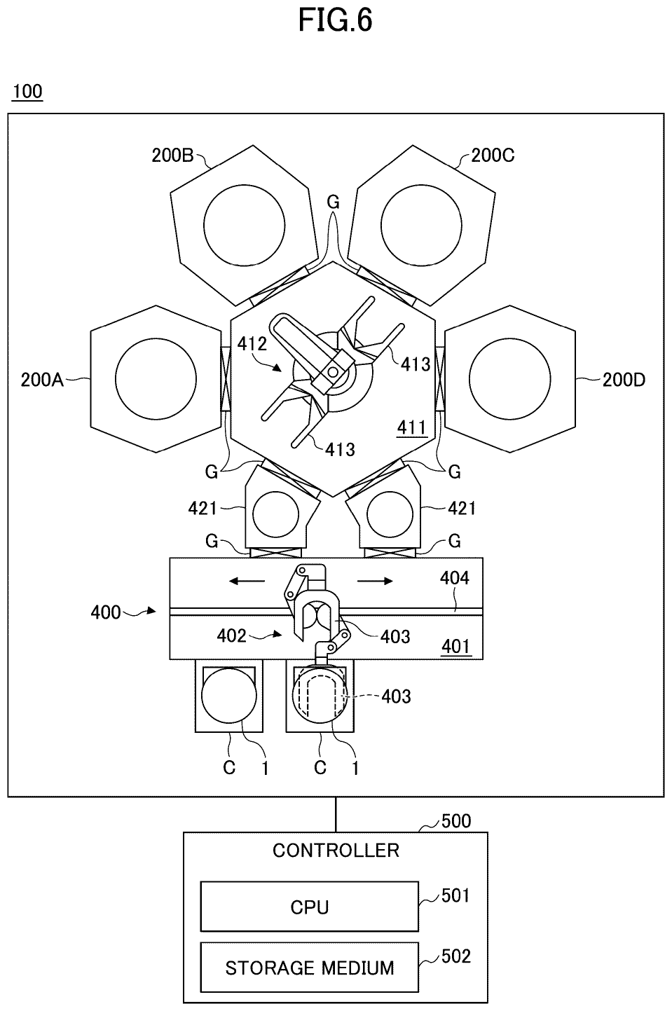

Next, a film forming apparatus 100 configured to perform the above film forming method will be described with reference to FIG. 6. As illustrated in FIG. 6, the film forming apparatus 100 includes a first processor 200A, a second processor 200B, a third processor 200C, a fourth processor 200D, a conveyor 400, and a controller 500. The first processor 200A is configured to perform step S2 of FIG. 1. The second processor 200B is configured to perform step S3 of FIG. 1. The third processor 200C is configured to perform step S4 of FIG. 1. The fourth processor 200D is configured to perform step S6 of FIG. 1. The first processor 200A, the second processor 200B, the third processor 200C, and the fourth processor 200D have similar structures. Therefore, only the first processor 200A can perform all of steps S2 to S4 and S6 as illustrated in FIG. 1. The first processor 200A, the second processor 200B, the third processor 200C, and the fourth processor 200D may have different structures. The conveyor 400 is configured to convey the substrate 1 to the first processor 200A, the second processor 200B, the third processor 200C, and the fourth processor 200D. The controller 500 is configured to control the first processor 200A, the second processor 200B, the third processor 200C, the fourth processor 200D, and the conveyor 400.

The conveyor 400 includes a first conveying chamber 401 and a first conveyor 402. The internal atmosphere of the first conveying chamber 401 is an open-air atmosphere. The first conveyor 402 is provided in the interior of the first conveying chamber 401. The first conveyor 402 includes an arm 403 configured to hold the substrate 1, and travels along a rail 404. The rail 404 extends in an alignment direction of a carrier C.

The conveyor 400 includes a second conveying chamber 411 and a second conveyor 412. The internal atmosphere of the second conveying chamber 411 is a vacuum atmosphere. The second conveyor 412 is provided in the interior of the second conveying chamber 411. The second conveyor 412 includes an arm 413 configured to hold the substrate 1, and the arm 413 is disposed so as to be movable in the vertical direction and the horizontal direction and so as to be rotatable about the vertical axis. The first processor 200A, the second processor 200B, the third processor 200C, and the fourth processor 200D are connected to the second conveying chamber 411 via different gate valves G.

Further, the conveyor 400 includes a load-lock chamber 421 between the first conveying chamber 401 and the second conveying chamber 411. The internal atmosphere of the load-lock chamber 421 is switched between the vacuum atmosphere and the open-air atmosphere by an unillustrated pressure adjuster. Thereby, the interior of the second conveying chamber 411 can always be maintained in the vacuum atmosphere. Also, the flow of gas from the first conveying chamber 401 into the second conveying chamber 411 can be suppressed. The gate valve G is provided between the first conveying chamber 401 and the load-lock chamber 421, and between the second conveying chamber 411 and the load-lock chamber 421.

The controller 500 is, for example, a computer and includes a CPU (Central Processing Unit) 501 and a storage medium 502, such as a memory or the like. The storage medium 502 stores programs controlling various processes performed in the film forming apparatus 100. The controller 500 causes the CPU 501 to execute the programs stored in the storage medium 502, thereby controlling how the film forming apparatus 100 works. The controller 500 controls the first processor 200A, the second processor 200B, the third processor 200C, the fourth processor 200D, and the conveyor 400, and performs the film forming method as described above.

Next, how the film forming apparatus 100 works will be described. First, the first conveyor 402 removes the substrate 1 from the carrier C, conveys the removed substrate 1 to the load-lock chamber 421, and exits the load-lock chamber 421. Next, the internal atmosphere of the load-lock chamber 421 is switched from the open-air atmosphere to the vacuum atmosphere. Subsequently, the second conveyor 412 removes the substrate 1 from the load-lock chamber 421, and conveys the removed substrate 1 to the first processor 200A.

Next, the first processor 200A performs step S2. Subsequently, the second conveyor 412 removes the substrate 1 from the first processor 200A, and conveys the removed substrate 1 to the second processor 200B. During this period, the ambient atmosphere of the substrate 1 can be maintained in the vacuum atmosphere, and oxidation of the substrate 1 can be suppressed.

Next, the second processor 200B performs step S3. Subsequently, the second conveyor 412 removes the substrate 1 from the second processor 200B, and conveys the removed substrate 1 to the third processor 200C. During this period, the ambient atmosphere of the substrate 1 can be maintained in the vacuum atmosphere.

Next, the third processor 200C performs step S4. Subsequently, the controller 500 checks whether or not steps S3 and S4 have been performed a set number of times. If the set number of times has not been reached, the second conveyor 412 removes the substrate 1 from the third processor 200C, and conveys the removed substrate 1 to the second processor 200B. Subsequently, the controller 500 controls the second processor 200B, the third processor 200C, and the conveyor 400, and performs steps S3 and S4.

Meanwhile, when the set number of times has been reached, the second conveyor 412 removes the substrate 1 from the third processor 200C, and conveys the removed substrate 1 to the fourth processor 200D. During this period, the ambient atmosphere of the substrate 1 can be maintained in the vacuum atmosphere, and degradation in the blocking performance of the SAM 17 can be suppressed.

Next, the fourth processor 200D performs step S6. Subsequently, the second conveyor 412 removes the substrate 1 from the fourth processor 200D, conveys the removed substrate 1 to the load-lock chamber 421, and exits the load-lock chamber 421. Subsequently, the internal atmosphere of the load-lock chamber 421 is switched from the vacuum atmosphere to the open-air atmosphere. Subsequently, the first conveyor 402 removes the substrate 1 from the load-lock chamber 421, and houses the removed substrate 1 in the carrier C. Thus, the process of the substrate 1 is ended.

Next, the first processor 200A will be described with reference to FIG. 7. The second processor 200B, the third processor 200C, and the fourth processor 200D are configured in the same manner as is the first processor 200A, and thus illustration and description thereof will be omitted.

The first processor 200A includes an approximately cylindrical airtight process chamber 210. An exhaust chamber 211 is provided at the center of the bottom wall of the process chamber 210. The exhaust chamber 211 has, for example, an approximately cylindrical shape that projects downward. An exhaust tube 212 is connected to the exhaust chamber 211, for example, on the side surface of the exhaust chamber 211.

An exhauster 272 is connected to the exhaust tube 212 via the pressure regulator 271. The pressure regulator 271 includes a pressure regulating valve, such as a butterfly valve or the like. The exhaust tube 212 is configured to reduce the internal pressure of the process chamber 210 by means of the exhauster 272. The pressure regulator 271 and the exhauster 272 constitute a gas discharger 270 configured to discharge the gas in the process chamber 210.

A conveyance port 215 is provided in the side surface of the process chamber 210. The conveyance port 215 is opened or closed by the gate valve G. Through the conveyance port 215, the substrate 1 is conveyed in and out between the interior of the process chamber 210 and the second conveying chamber 411 (see FIG. 6).

The process chamber 210 includes a stage 220 that is a holder configured to hold the substrate 1. The stage 220 horizontally holds the substrate 1 with the substrate surface 1a facing upward. The stage 220 is formed in an approximately circular shape in a plan view and is supported by a support 221. An approximately circular recess 222 configured to receive the substrate 1 having a diameter of, for example, 300 mm is formed at the surface of the stage 220. The recess 222 has an inner diameter that is slightly larger than the diameter of the substrate 1. The depth of the recess 222 is, for example, approximately the same as the thickness of the substrate 1. The stage 220 is formed of a ceramic material, such as aluminum nitride (AlN) or the like. The stage 220 may be formed of a metal material, such as nickel (Ni) or the like. Instead of the recess 222, a guide ring configured to guide the substrate 1 may be provided at the periphery of the surface of the stage 220.

For example, a grounded lower electrode 223 is buried in the stage 220. A heater 224 is buried under the lower electrode 223. The heater 224 is configured to heat the substrate 1 on the stage 220 to a set temperature by receiving a power from a power supply (not illustrated) in accordance with a control signal from the controller 500 (see FIG. 6). When the entire stage 220 is formed of metal, the entire stage 220 functions as a lower electrode. Thus, the lower electrode 223 does not need to be buried in the stage 220. The stage 220 is provided with multiple (e.g., three) raising-lowering pins 231 configured to hold and raise/lower the substrate 1 on the stage 220. A material of the raising-lowering pins 231 may be, for example, ceramics, such as alumina (Al₂O₃) or the like, or quartz or the like. The lower ends of the raising-lowering pins 231 are attached to a support plate 232. The support plate 232 is connected via a raising-lowering shaft 233 to a raising-lowering driver 234 that is provided externally of the process chamber 210.

The raising-lowering driver 234 is provided, for example, below the exhaust chamber 211. A bellows 235 is provided between the raising-lowering driver 234 and an opening 219 through which the raising-lowering shaft 233 passes. The opening 219 is formed in the lower surface of the exhaust chamber 211. The support plate 232 may have a shape that can be raised and lowered without interfering with the support 221 of the stage 220. The raising-lowering pins 231 are configured to be raised and lowered by the raising-lowering driver 234 between the upper surface of the stage 220 and the lower surface of the stage 220.

A gas supply 240 is provided in an upper wall 217 of the process chamber 210 via an insulating member 218. The gas supply 240 forms an upper electrode and faces the lower electrode 223. A high-frequency power supply 252 is connected to the gas supply 240 via a matcher 251. By supplying a high-frequency power of from 400 kHz through 40 MHz from the high-frequency power supply 252 to the upper electrode (gas supply 240), a high-frequency electric field is generated between the upper electrode (gas supply 240) and the lower electrode 223, and capacitively coupled plasma is generated. A plasma generator 250 configured to generate plasma includes the matcher 251 and the high-frequency power supply 252. The plasma generator 250 is not limited to a plasma generator configured to generate capacitively coupled plasma, but may be a plasma generator configured to generate different plasma, such as inductively coupled plasma or the like. In the steps in which no plasma is generated (e.g., steps S4 and S6), the gas supply 240 does not need to form the upper electrode and also there is no need to provide the lower electrode 223.

The gas supply 240 includes a hollow gas supply chamber 241. The lower surface of the gas supply chamber 241 is provided with numerous holes 242 that are, for example, disposed at equal intervals. The holes 242 are for dispersing and supplying the process gas into the process chamber 210. A heater 243 is buried, for example, above the gas supply chamber 241 in the gas supply 240. The heater 243 is heated to a set temperature by receiving a power from a power supply (not illustrated) in accordance with a control signal from the controller 500.

A gas supply 260 is connected to the gas supply chamber 241 through a gas supply path 261. The gas supply 260 is configured to supply the gas, used in at least one step of steps S2 to S4 and S6 of FIG. 1, to the gas supply chamber 241 through the gas supply path 261. Although not illustrated, for each of the types of gas, the gas supply 260 includes: an individual tube; an opening/closing valve, provided in a location partway along in the individual tube; and a flow rate regulator, provided in a location partway along in the individual tube. When the opening/closing valve opens the individual tube, gas is supplied from the supply source to the gas supply path 261. The amount of the gas supplied is controlled by the flow rate regulator. Meanwhile, when the opening/closing valve closes the individual tube, the supply of gas from the supply source to the gas supply path 261 is stopped.

### Experimental Data

Next, experimental data will be described. A water contact angle was measured using LSE-ME3 of NiCK Corporation. The water contact angle represents the density of the SAM. The SAM has hydrophobicity. Thus, a larger water contact angle is considered to indicate a higher density of the SAM.

### Example 1

In Example 1, steps S1, S3, and S4 of FIG. 1 were performed. In step S1, a substrate having a Ru film on a surface thereof was provided. The Ru film had been formed through PVD (Physical Vapor Deposition). In step S3, H₂O gas formed into plasma was supplied to the substrate surface. The process condition in step S3 was as follows.
Flow rate of H₂O gas: 100 sccm
Flow rate of Ar gas: 900 sccm
Power frequency for plasma generation: 40 MHz
Power for plasma generation: 200 W
Process time: 1 minute
Process temperature (substrate temperature): 150° C.
Process pressure: 266 Pa

In step S4, steps S41 and S42 as illustrated in FIG. 3 were each performed once in this order. In step S41, PFBA gas was supplied into the process chamber in a state in which the substrate was housed in the process chamber and the internal pressure of the process chamber was reduced. The process condition in step S41 was as follows.
Flow rate of PFBA gas: 50 sccm
Process time: 5 minutes
Process temperature: 150° C.
Process pressure: 160 Pa

In step S42, the state in which supply of the PFBA gas into the process chamber was stopped was maintained for a set period of time. The set period of time was 10 minutes (600 seconds), 20 minutes (1,200 seconds), 30 minutes (1,800 seconds), or 40 minutes (2,400 seconds). The process condition in step S42 was as follows.
Process time: 10 minutes, 20 minutes, 30 minutes, or 40 minutes
Process temperature: 150° C.
Process pressure: 52 Pa

For comparison, an experiment in which only step S41 was performed without performing step S42, i.e., an experiment in which the set period of time in step S42 was set to zero, was also performed.

### Example 2

In Example 2, the substrate surface was processed under the same condition as in Example 1 except that step S3 was not performed.

### Example 3

In Example 3, the substrate surface was processed under the same condition as in Example 1 except that H₂ gas formed into plasma was used in step S3 instead of H₂O gas formed into plasma. The process condition in step S3 was as follows.
Flow rate of H₂ gas: 2,000 sccm
Flow rate of Ar gas: 3,000 sccm
Power frequency for plasma generation: 40 MHz
Power for plasma generation: 200 W
Process time: 1 minute
Process temperature (substrate temperature): 150° C.
Process pressure: 266 Pa

### Evaluation of the Substrate Obtained in Examples 1 to 3

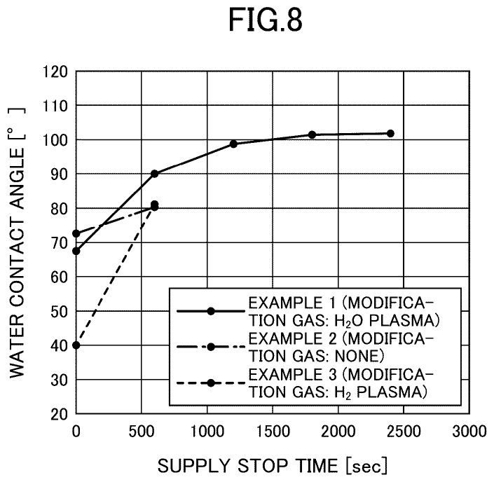

FIG. 8 illustrates a relationship between the water contact angle of the substrate surface obtained in Examples 1 to 3, and the supply stop time of the PFBA gas. FIG. 8 indicates that the water contact angle increases, i.e., the density of the SAM increases, by supplying the H₂O gas formed into plasma to the surface of the Ru film, supplying the PFBA gas to the surface of the Ru film, and then stopping the supply of the PFBA gas for 5 minutes (300 seconds) or longer.

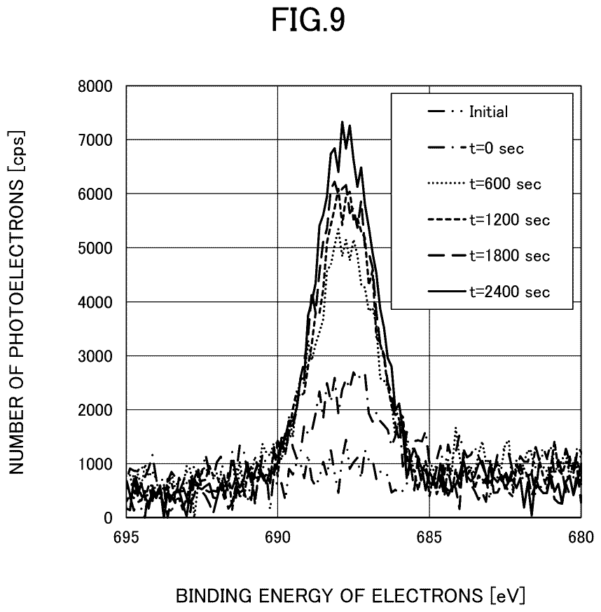

FIG. 9 illustrates a relationship between the peak of F in the XPS (X-ray photoelectron spectroscopy) spectrum of the substrate surface obtained in Example 1, and the supply stop time of the PFBA gas. In FIG. 9, t denotes the supply stop time of the PFBA gas. In FIG. 9, “Initial” is an XPS spectrum of the surface of the Ru film before performing steps S3 and S4. FIG. 9 indicates that a longer supply stop time of the PEBA gas leads to a higher peak of F and a higher density of the SAM.

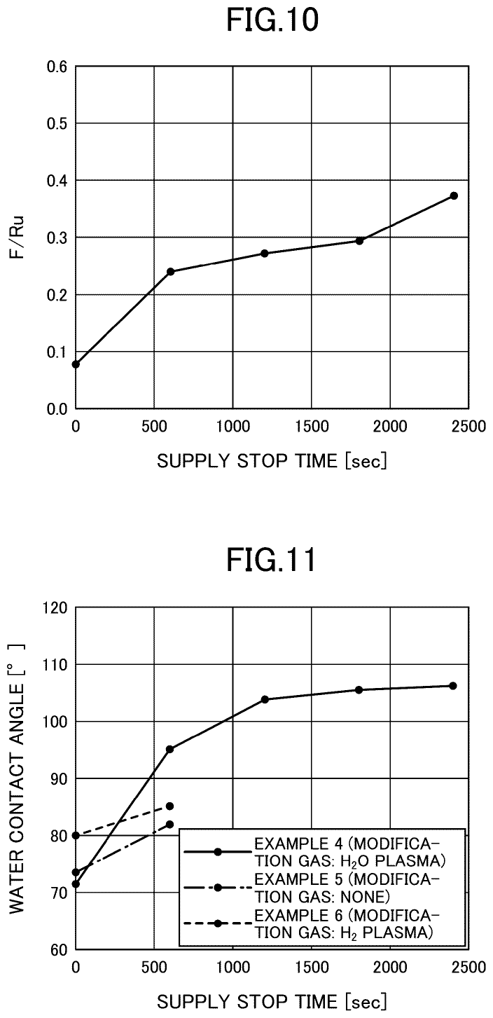

FIG. 10 illustrates a relationship between the atomic ratio of F to Ru determined from the XPS (X-ray photoelectron spectroscopy) spectrum of the substrate surface obtained in Example 1, and the supply stop time of the PFBA gas. In FIG. 10, the horizontal axis indicates the supply stop time of the PFBA gas, and the vertical axis indicates the atomic ratio of F to Ru (F/Ru). FIG. 10 indicates that a longer supply stop time of the PFBA gas leads to a higher atomic ratio of F to Ru and a higher density of the SAM.

Table 1 summarizes the evaluation results of Examples 1 to 3.

TABLE 1

| | | | PFBA gas | Water | |
|---|---|---|---|---|---|
| | | | supply stop | contact | |
| | Substrate | Modification | time | angle | |
| | surface | gas | [sec] | [°] | F/Ru |
| Example 1 | PVD | H₂O plasma | 0 | 67.7 | 0.08 |
| | Ru film | | 600 | 90.2 | 0.24 |
| | | | 1,200 | 98.8 | 0.27 |
| | | | 1,800 | 101.7 | 0.29 |
| | | | 2,400 | 101.9 | 0.37 |
| Example 2 | | — | 0 | 72.7 | |
| | | | 600 | 80.3 | |
| Example 3 | | H₂ plasma | 0 | 40.3 | |
| | | | 600 | 81.3 | |

### Example 4

In Example 4, the substrate surface was processed under the same condition as in Example 1 except for providing a substrate having a Ru film formed through CVD on the surface thereof.

### Example 5

In Example 5, the substrate surface was processed under the same condition as in Example 4 except that step S3 was not performed.

### Example 6

In Example 6, the substrate surface was processed under the same condition as in Example 4 except that the H₂ gas formed into plasma was used in step S3 instead of the H₂O gas formed into plasma. The process condition in step S3 was the same as that in Example 3.

### Evaluation of the Substrates Obtained in Examples 4 to 6

FIG. 11 illustrates a relationship between the water contact angle of the substrate surface obtained in Examples 4 to 6, and the supply stop time of the PFBA gas. FIG. 11 indicates that the water contact angle increases, i.e., the density of the SAM increases, by supplying the H₂O gas formed into plasma to the surface of the Ru film, supplying the PFBA gas to the surface of the Ru film, and then stopping the supply of the PFBA gas for 5 minutes (300 seconds) or longer.

Table 2 summarizes the evaluation results of Examples 4 to 6.

TABLE 2

| | | | PFBA gas | Water |
|---|---|---|---|---|
| | | | supply stop | contact |
| | Substrate | Modification | time | angle |
| | surface | gas | [sec] | [°] |
| Example 4 | CVD | H₂O plasma | 0 | 71.5 |
| | Ru film | | 600 | 95.0 |
| | | | 1,200 | 103.7 |
| | | | 1,800 | 105.5 |
| | | | 2,400 | 106.0 |
| Example 5 | | — | 0 | 73.6 |
| | | | 600 | 81.9 |
| Example 6 | | H₂ plasma | 0 | 79.7 |
| | | | 600 | 85.2 |

### Examples 7 to 13

In Examples 7 to 13, in the same manner as in Example 1, the substrate surface (i.e., the surface of the Ru film formed through PVD) was processed except for the presence or absence of step S3 and the process condition thereof. The presence or absence of step S3 and the process condition thereof were as follows. In Example 7, H₂ gas formed into plasma was supplied to the substrate surface. In Example 8, a gas mixture containing H₂ gas and N₂ gas and formed into plasma was supplied to the substrate surface. In Example 9, O₂ gas formed into plasma was supplied to the substrate surface. In Example 10, step S3 was not performed. In Example 11, O₃ gas generated through UV irradiation and not formed into plasma was supplied to the substrate surface. In Example 12, O₂ gas not formed into plasma was supplied to the substrate surface. In Example 13, H₂O gas formed into plasma was supplied to the substrate surface.

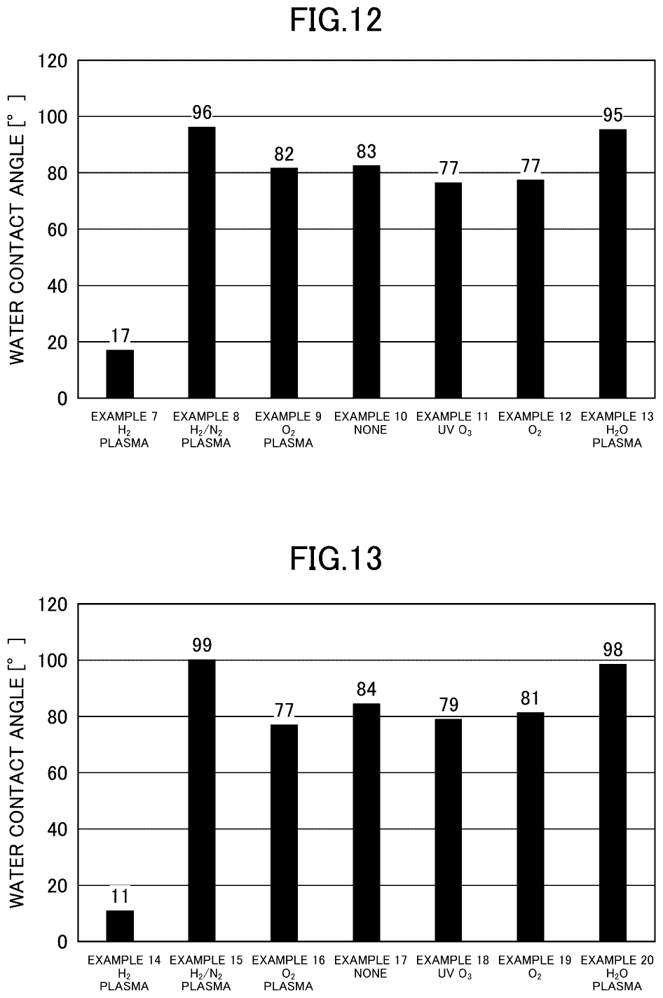

FIG. 12 illustrates the water contact angle of the substrate surface obtained in Examples 7 to 13. FIG. 12 indicates that compared to the example in which step S3 is not performed, the water contact angle increases, i.e., the density of the SAM increases, by supplying the H₂O gas formed into plasma to the surface of the Ru film or supplying the gas mixture containing H₂ gas and N₂ gas and formed into plasma to the substrate surface before supplying the PFBA gas to the surface of the Ru film.

### Examples 14 to 20

In Examples 14 to 20, in the same manner as in Example 4, the substrate surface (i.e., the surface of the Ru film formed through CVD) was processed except for the presence or absence of step S3 and the process condition thereof. The presence or absence of step S3 and the process condition thereof were as follows. In Example 14, H₂ gas formed into plasma was supplied to the substrate surface. In Example 15, a gas mixture containing H₂ gas and N₂ gas and formed into plasma was supplied to the substrate surface. In Example 16, O₂ gas formed into plasma was supplied to the substrate surface. In Example 17, step S3 was not performed. In Example 18, O₃ gas generated through UV irradiation and not formed into plasma was supplied to the substrate surface. In Example 19, O₂ gas not formed into plasma was supplied to the substrate surface. In Example 20, H₂O gas formed into plasma was supplied to the substrate surface.

FIG. 13 illustrates the water contact angle of the substrate surface obtained in Examples 14 to 20. FIG. 13 indicates that compared to the example in which step S3 is not performed, the water contact angle increases, i.e., the density of the SAM increases, by supplying the H₂O gas formed into plasma to the surface of the Ru film or supplying the gas mixture containing H₂ gas and N₂ gas and formed into plasma to the substrate surface, before supplying the PFBA gas to the surface of the Ru film.

Although the embodiments of the film forming method and the film forming apparatus according to the present disclosure have been described above, the present disclosure is not limited to the above embodiments and the like. Various changes, modifications, substitutions, additions, deletions, and combinations are possible within the scope of the claims recited. These are also within the technical scope of the present disclosure.

The present application claims priority to Japanese Patent Application No. 2022-001109, filed with the Japan Patent Office on Jan. 6, 2022, and the entire contents of Japanese Patent Application No. 2022-001109 are incorporated in the present application by reference.

### REFERENCE SIGNS LIST

1 Substrate
1a Substrate surface
11 Insulating film (first film)
12 Conductive film (second film)
17 SAM (self-assembled monolayer)

1. A film forming method, comprising:
(A) providing a substrate including a first film and a second film in different regions of a surface of the substrate, the second film being formed of a material different from a material of the first film;
(B) supplying modification gas formed into plasma to the surface of the substrate, thereby modifying the surface of the substrate; and
(C) after (B), selectively forming a self-assembled monolayer on a surface of the second film rather than a surface of the first film, wherein
the modification gas used in (B) contains hydrogen and oxygen or contains hydrogen and nitrogen, and
(C) includes
(Ca) supplying gas of carboxylic acid to a process chamber in a state in which the substrate is housed in the process chamber and an internal pressure of the process chamber is reduced, the gas of carboxylic acid being a precursor of the self-assembled monolayer, and
(Cb) maintaining, for a set period of time, a state in which supply of the gas of the carboxylic acid to the process chamber is stopped or a state in which a flow rate of the gas of the carboxylic acid supplied is reduced compared to (Ca).

2. The film forming method according to claim 1, wherein
the set period of time in (Cb) is from 5 minutes through 1 hour.

3. The film forming method according to claim 1, wherein
(Cb) includes maintaining, for the set period of time, a state in which supply of all of gases to the process chamber is stopped.

4. The film forming method according to claim 1, wherein
an internal pressure of the process chamber in (Cb) is lower than an internal pressure of the process chamber in (Ca).

5. The film forming method according to claim 1, wherein
an internal pressure of the process chamber in (Cb) is from 10 Pa through 100 Pa.

6. The film forming method according to claim 1, wherein
an internal pressure of the process chamber in (Ca) is from 100 Pa through 300 Pa.

7. The film forming method according to claim 1, wherein
the carboxylic acid used in (Ca) includes at least one carboxylic acid selected from the group consisting of CF₃(CF₂)₂COOH, CF₃COOH, C₆H₅COOH, and CH₃(CH₂)ₙCOOH, where n is an integer of from 2 through 10.

8. The film forming method according to claim 1, wherein
(C) includes repeatedly performing (Ca) and (Cb).

9. The film forming method according to claim 1, wherein
the modification gas used in (B) is H₂O gas, a gas mixture of H₂ and O₂, or a gas mixture of H₂ and O₃.

10. The film forming method according to claim 1, wherein
the modification gas used in (B) is a gas mixture of H₂ and N₂, or NH₃ gas.

11. The film forming method according to claim 1, wherein
the film forming method includes repeatedly performing (B) and (C).

12. The film forming method according to claim 1, wherein
the first film is an insulating film, and the second film is a conductive film.

13. The film forming method according to claim 12, wherein
the conductive film is a Cu film, a Co film, a Ru film, or a W film.

14. The film forming method according to claim 1, further comprising:
(D) cleaning the surface of the substrate before (B).

15. The film forming method according to claim 14, wherein
(D) includes supplying a reductive gas formed into plasma to the surface of the substrate.

16. The film forming method according to claim 1, further comprising:
(E) after (C), forming a target film on the surface of the first film while inhibiting formation of the target film on the surface of the second film using the self-assembled monolayer.

17. A film forming apparatus, comprising:
a process chamber;
a holder configured to hold a substrate in an interior of the process chamber;
a gas supply configured to supply gas to the interior of the process chamber;
a gas exhauster configured to exhaust the gas from the interior of the process chamber;
a conveyor configured to convey the substrate into or out of the process chamber; and
a controller including a processor and a memory storing one or more programs, which when executed, cause the processor to:
control the gas supply, the gas exhauster, and the conveyor, and perform the film forming method of claim 1.
